(19) United States
(12) Patent Application Publication
(10) Pub. No.: US 2026/0194707 A1
(43) Pub. Date: Jul. 9, 2026

(54) CIRCUIT SUBSTRATE WITH LIQUID-COOLING LOOP AND OPTICAL COMMUNICATION MODULE HAVING THE SAME

(71) Applicant: AEON SUPER AI INC., New Taipei City (TW)

(72) Inventor: Chien-Kuo LIANG, New Taipei City (TW)

(21) Appl. No.: 19/079,476

(22) Filed: Mar. 14, 2025

(30) Foreign Application Priority Data
Jan. 8, 2025 (TW) 114100738

(51) Int. Cl. G02B 6/12

(52) U.S. Cl. CPC G02B 6/12004; G02B 2006/12038; G02B 2006/12135; G02B 2006/12142

(57) ABSTRACT

A circuit substrate with a liquid-cooling loop and an optical communication module having the same are provided. The circuit substrate includes a circuit layer and a sealing layer. The circuit layer is made of a glass material, and includes a surface and an electricity-conductive layer arranged on the surface. At least one optical communication unit is electrically connected onto the electricity-conductive layer. The sealing layer is made of the glass material, and is stacked under another surface of the circuit layer to seal the circuit layer. A channel structure is arranged between the circuit layer and the sealing layer, and correspondingly through under the optical communication unit. Two channel holes of the channel structure connected to each other are arranged on the circuit layer or the sealing layer. A coolant is therefore injected through the two channel holes to help the optical communication unit dissipate heat.

### BACKGROUND OF THE DISCLOSURE

### Technical Field

The present disclosure relates to a circuit board, and especially relates to a circuit substrate with a liquid-cooling loop that may be used for cooling in the optical communication field, and especially relates to an optical communication module having the same.

### Description of Related Art

Most of today's computers or servers use electrical signals to perform data calculations. However, for occasions such as AI servers which require higher transmission rates, electrical signals or optical signals may be used for data transmission. Since the bandwidth of the optical signal is much higher than the bandwidth of the electrical signal, currently the signal transmission between servers in most data centers use optical signals. The server first converts the “on and off” of the electrical signal into the “bright and dark” of the optical signal through the “optical transmitting module”, and then transmits the optical signal to the optical fiber, and then transmits the optical signal to the receiving end, and then converts the “bright and dark” of the optical signal into the “on and off” of the electrical signal through the “optical receiving module”.

However, since the transmission rate mentioned above is fast and relatively the high heat is generated, solving the heat dissipation problem through the existing methods is difficult.

In view of this, to improve and solve the above-mentioned deficiencies, the inventor has devoted himself to research and combined with the application of the academic theory, and finally provides the present disclosure that is reasonably designed and effectively improves the above-mentioned deficiencies.

### SUMMARY OF THE INVENTION

The main object of the present disclosure is to provide a circuit substrate with a liquid-cooling loop and to provide an optical communication module having the same. The circuit substrate is made of, for example, a glass material. A channel for being injected a coolant is formed in the circuit substrate, which may effectively help the optical communication module dissipate heat.

To achieve the object mentioned above, the present disclosure provides a circuit substrate with a liquid-cooling loop. The circuit substrate includes a circuit layer and a sealing layer. The circuit layer is made of a glass material, and includes a surface and an electricity-conductive layer which is arranged on the surface. At least one optical communication unit is electrically connected onto the electricity-conductive layer. The sealing layer is made of the glass material, and is stacked under another surface of the circuit layer to seal the circuit layer. Moreover, a channel structure of the circuit substrate is arranged between the circuit layer and the sealing layer, and is correspondingly to be through under the optical communication unit. Two channel holes (which are connected to each other) of the channel structure are arranged on the circuit layer or the sealing layer.

To achieve the object mentioned above, the present disclosure provides an optical communication module including a circuit substrate, a processing unit, and at least one optical communication unit. The circuit substrate includes a circuit layer and a sealing layer which are made of a glass material. The circuit layer includes a surface and an electricity-conductive layer which is arranged on the surface. The at least one optical communication unit is electrically connected onto the electricity-conductive layer. The sealing layer is stacked under another surface of the circuit layer to seal the circuit layer. The processing unit is electrically connected onto the electricity-conductive layer. The optical communication unit is also electrically connected onto the electricity-conductive layer, and transmits signals with the processing unit. Moreover, a channel structure of the circuit substrate is arranged between the circuit layer and the sealing layer, and correspondingly through under the optical communication unit. Two channel holes (which are connected to each other) of the channel structure are arranged on the circuit layer or the sealing layer.

### BRIEF DESCRIPTION OF THE DRAWINGS

FIG. 1 shows a three-dimensional schematic diagram of the optical communication module of the present disclosure.

FIG. 2 shows a three-dimensional exploded schematic view of the first embodiment of the circuit substrate of the present invention disclosure.

FIG. 3 shows a partial cross-sectional schematic view of the first embodiment of the present disclosure.

FIG. 4 shows a plane top-view schematic diagram of the present disclosure adding the liquid supply apparatus.

FIG. 5 shows a three-dimensional exploded schematic view of the second embodiment of the circuit substrate of the present invention disclosure.

FIG. 6 shows a partial cross-sectional schematic view of the second embodiment of the present disclosure.

### DETAILED DESCRIPTION

To enable the examiner to further understand the features and technical content of the present disclosure, please refer to the following detailed description and drawings of the present disclosure. However, the attached drawings are only for reference and illustration, and are not intended to limit the present disclosure.

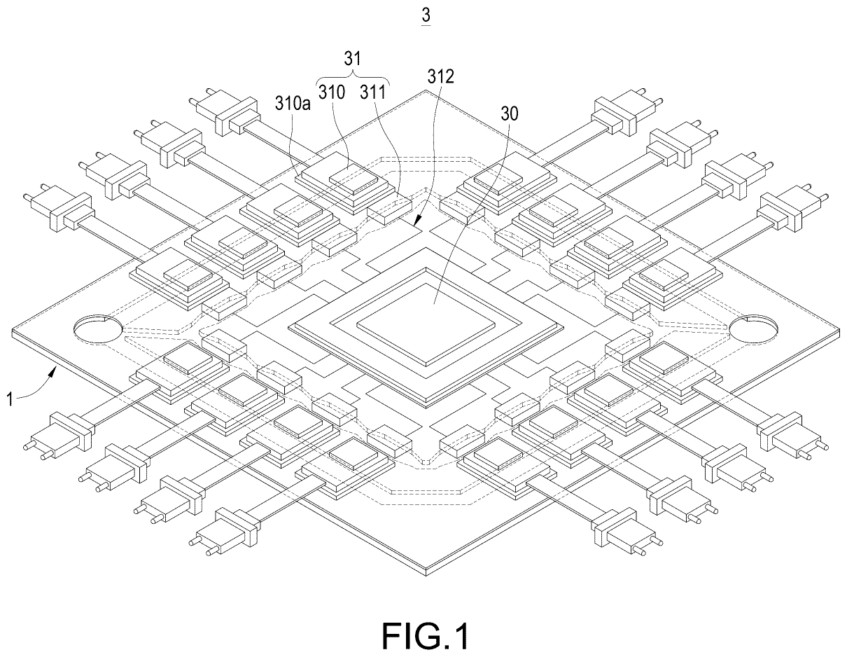

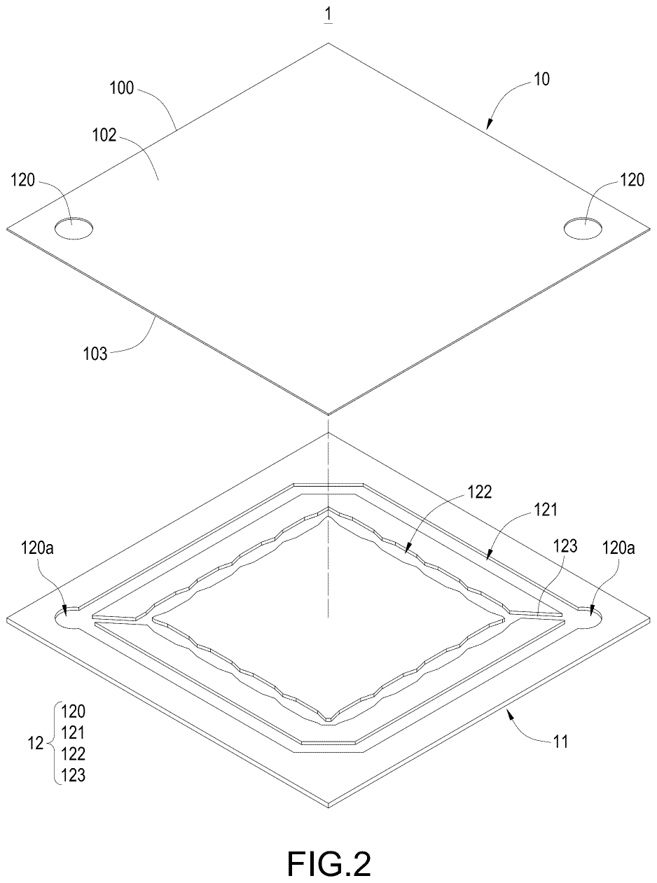

FIG. 1 shows a three-dimensional schematic diagram of the optical communication module 3 of the present disclosure. The present disclosure provides a circuit substrate 1 with a liquid-cooling loop, and provides an optical communication module 3 having the same. The circuit substrate 1 may accommodate a processing unit 30 and at least one optical communication unit 31 arranged thereon to form the optical communication module 3. The optical communication module 3 may be used in communication applications such as AI servers. As shown in FIG. 2, the circuit substrate 1 includes a circuit layer 10 and a sealing layer 11 which is stacked under the circuit layer 10 for sealing.

The circuit layer 10 may be made of a glass material or other materials. The circuit layer 10 includes a surface 100 which is opposite to the sealing layer 11. The surface 100 may face upward. An electricity-conductive layer 102 (of the circuit layer 10), such as a copper foil circuit, is arranged on the surface 100, so that the processing unit 30 and the optical communication unit 31 mentioned above may be arranged on the circuit layer 10 and electrically connected.

Possible embodiments of the processing unit 30 include but are not limited to a data center switch chip and an artificial intelligence (AI) chip. The processing unit 30 is connected to each optical communication unit 31 through a plurality of optical waveguides or electrical trace interconnects on the circuit substrate 1 to transmit signals 312.

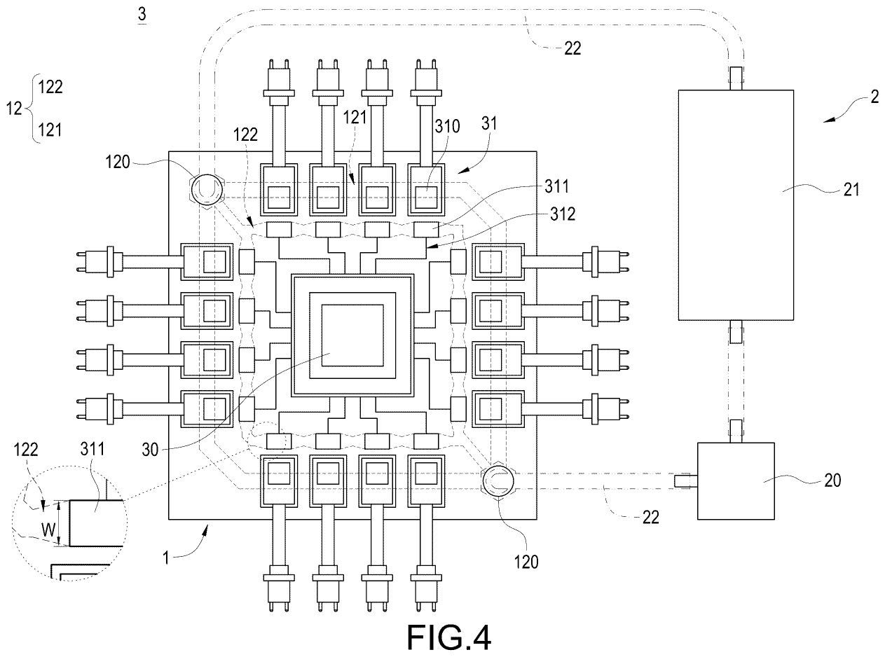

The sealing layer 11 may also be made of the glass material or other materials. The sealing layer 11 is stacked under the circuit layer 10. The sealing layer 11 and the circuit layer 10 are sealed. At least one channel structure 12 is arranged between the circuit layer 10 and the sealing layer 11 to correspond to the processing unit 30 and a bottom part of the optical communication unit 31 which are arranged on the circuit layer 10. The channel structure 12 includes at least two channel holes 120 which are connected to each other on the circuit layer 10 or the sealing layer 11 for the circuit substrate 1 to be connected to a liquid supply apparatus 2, as shown in FIG. 4. The liquid supply apparatus 2 may at least include a pump 20, a cooling grid 21, and a plurality of pipelines 22 for connecting the pump 20 and the cooling grid 21 in series, and have a coolant injected therein. Each of the pipelines 22 is connected to the two channel holes 120 respectively, so that after the coolant is injected from one of the channel holes 120 through the pump 20, through the channel structure 12 the coolant flows back from the other channel hole 120 to the cooling grid 21 for cooling, and then the coolant circulates. Specifically, the channel structure 12 may be recessed on a lower surface of the circuit layer 100, namely, another surface 103 opposite to the surface 100 mentioned above. The channel structure 12 may also be recessed on the sealing layer 11, namely, a surface of the sealing layer 11 where the sealing layer 11 and the circuit layer 10 are joined. The channel structure 12 may also be recessed on the circuit layer 10 and the sealing layer 11 respectively. In the embodiment of the present disclosure, the channel structure 12 is mainly recessed on the sealing layer 11. The two channel holes 120 are arranged on the circuit layer 10. The channel structure 12 includes at least a first channel 121 and at least a second channel 122 connected with the two channel holes 120. The channel structure 12 further includes at least a connecting channel 123 arranged between the first channel 121 and the second channel 122, so that the first channel 121 and the second channel 122 are connected. The channel structure 12 further includes a liquid injection area 120a arranged in the first channel 121 or the second channel 122 relative to the two channel holes 120 respectively, so that the injected coolant may be buffered when the coolant enters the channel structure 12, and then flow into the channel (for example, the first channel 121 and the second channel 122) when the coolant is accumulated enough.

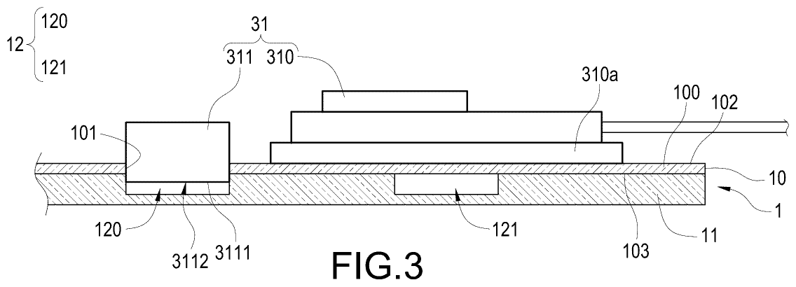

As shown in FIG. 3 and FIG. 4, the processing unit 30 mentioned above is used to transmit the signals 312 with each optical communication unit 31. Each optical communication unit 31 may include an electronic-photonic integrated circuit (EPIC) 310 and an optical signal chip 311. The electronic-photonic integrated circuit 310 may be packaged on a chip board 310a and soldered to the electricity-conductive layer 102 on the surface 100 of the circuit layer 10. In the embodiment of the present disclosure, the electronic-photonic integrated circuit 310 may be a single composite functional chip which integrates an electronic integrated circuit (EIC) and a photonic integrated circuit (PIC) through the co-packaged optics (CPO) technology. The electronic-photonic integrated circuit 310 is used to modulate or convert optical signals transmitted from the connected optical fiber connector (not shown in the drawings) into electrical signals and transmit the electrical signals to the processing unit 30; or the electronic-photonic integrated circuit 310 uses the electrical signal transmitted by the processing unit 30 to drive the optical signal chip 311 to emit the light source and convert the light source into the optical signal, and then guides the optical signal to the optical fiber connector through the optical waveguide in the electronic-photonic integrated circuit 310, and then the optical signal is transmitted to the outside. Moreover, the optical signal chip 311 may be a laser source (for example, a laser diode (LD)) and is controlled by the electronic-photonic integrated circuit 310.

In the embodiment of the present disclosure, the optical signal chip 311 may be electrically connected to perform the signal exchange through the optical waveguide or the electrical trace interconnect (not shown in the drawings) arranged on the electricity-conductive layer 102 on the surface 100 of the circuit layer 10. In other feasible embodiments, the optical signal chip 311 and the electronic-photonic integrated circuit 310 may also be packaged together on the chip board 310a through, for example, the co-packaged optics (CPO) technology for the silicon photonics. Therefore, the first channels 121 mentioned above is through under each of the electronic-photonic integrated circuits 310 or the chip board 310a. The second channels 122 mentioned above is through under each of the optical signal chips 311, thereby providing the heat dissipation needs of each of the optical communication units 31. Further, the circuit layer 10 is provided with at least one through hole 101 for each optical signal chip 311 to sink partially, so that a bottom surface 3111 of each optical signal chip 311 sinks into the circuit layer 10 through the through hole 101, and the bottom surface 3111 of each optical signal chip 311 is immersed in the second channel 122, so that the coolant flowing through the second channel 122 mentioned above may directly contact the bottom surface 3111 of each optical signal chip 311, so as to improve the cooling effect. In other feasible embodiments, each optical signal chip 311 includes a thermal-conductive layer 3112 arranged on the bottom surface 3111 of the optical signal chip 311. The thermal-conductive layer 3112 may be a graphene, a diamond, or a composite of the graphene and the diamond, thereby improving the thermal conduction efficiency.

Moreover, as shown in FIG. 4, a width W of the second channel 122 is formed and increases from narrow to wide toward each optical signal chip 311, thereby having the effect of accelerating the flow of the coolant.

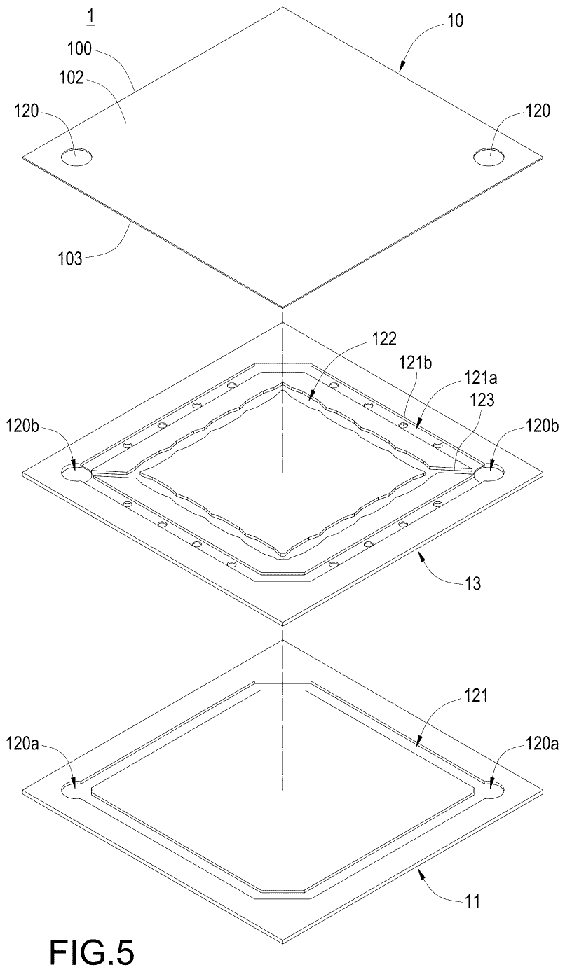

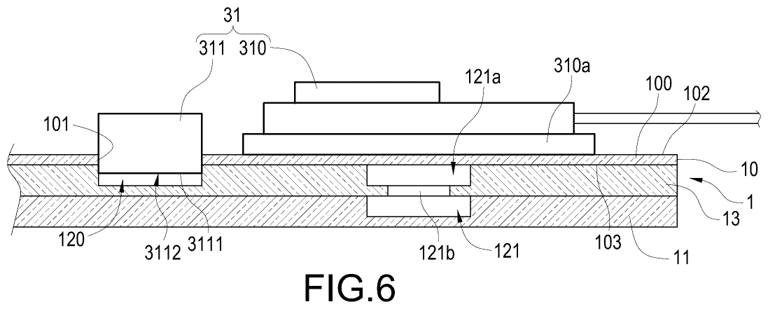

Moreover, as shown in FIG. 5 and FIG. 6, the circuit substrate 1 may further include at least one interlayer 13 arranged between the circuit layer 10 and the sealing layer 11, so that a part of the channel structure 12 may also be arranged on the interlayer 13. The interlayer 13 may be provided with two second through holes 120b corresponding to the two channel holes 120 respectively. In the embodiment of the present disclosure, the first channel 121 mentioned above may be arranged on the sealing layer 11. The second channel 122 is arranged on the interlayer 13. The channel structure 12 further includes a third channel 121a arranged on the interlayer 13 and corresponding to the first channel 121. The third channel 121a may be provided with a plurality of third through holes 121b connected with the first channel 121 located below, thereby making the coolant flow more varied and improving the fluidity. In the embodiment, the connecting channel 123 mentioned above is located on the interlayer 13, and connected with the second channel 122 and the third channel 121a.

Therefore, through the structure and the constitution mentioned above, the circuit substrate 1 with the liquid-cooling loop and the optical communication module 3 having the same of the present disclosure may be obtained.

To sum up, the present disclosure may indeed achieve the object of the use described in the above description to solve the deficiencies of the prior arts. Because the present disclosure is novel and nonobvious, which fully meets the requirements for the invention patent application, the application is filed in accordance with the patent law and required to be examined for details to grant a patent for the present disclosure to protect the rights of the inventor.

However, the above descriptions are only the better and possible embodiments of the present disclosure and do not limit the patent scope of the present disclosure. Therefore, any equivalent technologies, means, and other changes made by using the contents of the descriptions and drawings of the present disclosure are equally applicable and included in the scope of the present disclosure, which is stated here.

What is claimed is:

1. A circuit substrate with a liquid-cooling loop, the circuit substrate comprising:
a circuit layer made of a glass material, and comprising a surface and an electricity-conductive layer arranged on the surface, wherein at least one optical communication unit is electrically connected onto the electricity-conductive layer; and
a sealing layer made of the glass material, and stacked under another surface of the circuit layer to seal the circuit layer,
wherein a channel structure of the circuit substrate is arranged between the circuit layer and the sealing layer, and correspondingly through under the optical communication unit; two channel holes of the channel structure connected to each other are arranged on the circuit layer or the sealing layer.

2. The circuit substrate of the claim 1, wherein the two channel holes are connected to a liquid supply apparatus.

3. The circuit substrate of the claim 2, wherein the liquid supply apparatus comprises a pump, a cooling grid, and a plurality of pipelines for connecting the pump and the cooling grid in series, and each of the pipelines is connected to the two channel holes respectively.

4. The circuit substrate of the claim 1, wherein the channel structure is recessed on the another surface of the circuit layer, or is recessed on the sealing layer, or is recessed on the circuit layer and the sealing layer respectively.

5. The circuit substrate of the claim 1, wherein the optical communication unit comprises an electronic-photonic integrated circuit and an optical signal chip; the channel structure comprises at least a first channel and at least a second channel connected with the two channel holes and corresponding to the electronic-photonic integrated circuit and the optical signal chip respectively.

6. The circuit substrate of the claim 5, wherein the channel structure further comprises at least a connecting channel arranged between the first channel and the second channel.

7. The circuit substrate of the claim 5, wherein the circuit layer is provided with at least one through hole for the optical signal chip to sink partially, so that a bottom surface of the optical signal chip sinks into the circuit layer through the through hole, and the bottom surface of the optical signal chip is immersed in the channel structure.

8. The circuit substrate of the claim 5, wherein a width of the channel structure is formed and increases from narrow to wide toward the optical signal chip.

9. The circuit substrate of the claim 5, wherein the optical signal chip comprises a thermal-conductive layer arranged on a bottom surface of the optical signal chip.

10. The circuit substrate of the claim 9, wherein the thermal-conductive layer is a graphene, a diamond, or a composite of the graphene and the diamond.

11. The circuit substrate of the claim 1, further comprising an interlayer arranged between the circuit layer and the sealing layer, so that the channel structure is through the interlayer.

12. An optical communication module comprising:
a circuit substrate comprising a circuit layer and a sealing layer made of a glass material, the circuit layer comprising a surface and an electricity-conductive layer arranged on the surface, the sealing layer stacked under another surface of the circuit layer to seal the circuit layer;
a processing unit electrically connected onto the electricity-conductive layer; and
at least one optical communication unit electrically connected onto the electricity-conductive layer, and transmitting signals with the processing unit,
wherein a channel structure of the circuit substrate is arranged between the circuit layer and the sealing layer, and correspondingly through under the optical communication unit; two channel holes of the channel structure connected to each other are arranged on the circuit layer or the sealing layer.

13. The optical communication module of the claim 12, wherein the two channel holes are connected to a liquid supply apparatus.

14. The optical communication module of the claim 13, wherein the liquid supply apparatus comprises a pump, a cooling grid, and a plurality of pipelines for connecting the pump and the cooling grid in series, and each of the pipelines is connected to the two channel holes respectively.

15. The optical communication module of the claim 12, wherein the channel structure is recessed on the another surface of the circuit layer, or is recessed on the sealing layer, or is recessed on the circuit layer and the sealing layer respectively.

16. The optical communication module of the claim 12, wherein the optical communication unit comprises an electronic-photonic integrated circuit and an optical signal chip; the channel structure comprises at least a first channel and at least a second channel connected with the two channel holes and corresponding to the electronic-photonic integrated circuit and the optical signal chip respectively.

17. The optical communication module of the claim 16, wherein the channel structure further comprises at least a connecting channel arranged between the first channel and the second channel.

18. The optical communication module of the claim 16, wherein the circuit layer is provided with at least one through hole for the optical signal chip to sink partially, so that a bottom surface of the optical signal chip sinks into the circuit layer through the through hole, and the bottom surface of the optical signal chip is immersed in the channel structure.

19. The optical communication module of the claim 16, wherein a width of the channel structure is formed and increases from narrow to wide toward the optical signal chip.

20. The optical communication module of the claim 16, wherein the optical signal chip comprises a thermal-conductive layer arranged on a bottom surface of the optical signal chip.

21. The optical communication module of the claim 20, wherein the thermal-conductive layer is a graphene, a diamond, or a composite of the graphene and the diamond.

22. The optical communication module of the claim 21, wherein the circuit substrate further comprises an interlayer arranged between the circuit layer and the sealing layer, so that the channel structure is through the interlayer.
